(19) United States
(12) Patent Application Publication
(10) Pub. No.: US 2025/0105041 A1
(43) Pub. Date: Mar. 27, 2025

(54) SUBSTRATE TRANSPORTING DEVICE AND SUBSTRATE PROCESSING DEVICE EQUIPPED WITH THE SAME

(71) Applicant: SCREEN Holdings Co., Ltd., Kyoto (JP)

(72) Inventors: Hiroyuki KAWAHARA, Kyoto (JP); Takashi OTA, Kyoto (JP); Takuya SATO, Kyoto (JP); Fujikazu KITAMURA, Kyoto (JP)

(21) Appl. No.: 18/890,735

(22) Filed: Sep. 19, 2024

(30) Foreign Application Priority Data
Sep. 21, 2023 (JP) 2023-155675

(51) Int. Cl. H01L 21/67; B65G 47/90; H01L 21/68; H01L 21/687

(52) U.S. Cl. CPC H01L 21/67288; B65G 47/90; H01L 21/681; H01L 21/68707

(57) ABSTRACT

A substrate transporting device for transporting a substrate with a carrier capable of stacking and accommodating a plurality of substrates with a gap and having a carry-in/out port on one side surface includes the following. The device includes a transporting unit including a holding hand that holds the substrate, and being configured to transport the substrate by advancing/retreating the holding hand to/from the carry-in/out port of the carrier to a gap between the substrates; an acquisition unit configured to acquire shape information of the substrate when the substrate is viewed in an advancing/retreating direction of the holding hand from the carry-in/out port side while the substrate is accommodated; and a control unit configured to control the transporting unit based on the shape information; where the acquisition unit obtains the shape information by irradiating light in a wavelength region longer than visible light from the advancing/retreating direction of the holding hand.

### BACKGROUND OF THE INVENTION

### (1) Field of the Invention

The present invention relates to a substrate transporting device and a substrate processing device equipped with the same. The substrate is, for example, a semiconductor wafer, a liquid crystal display substrate, an organic electroluminescence (EL) substrate, a flat panel display (FPD) substrate, an optical display substrate, a magnetic disk substrate, an optical disk substrate, a magneto-optical disk substrate, a photomask substrate, or a solar cell substrate.

### (2) Description of the Related Art

Conventionally, as this type of device, there is a device including a cassette that accommodates a substrate, a substrate transporting mechanism that carries the substrate out from the cassette and carries the substrate into a substrate processing device, and an imaging means configured to image the substrate accommodated in the cassette, in which the substrate accommodated in the cassette is imaged, the shape of the substrate is determined based on the imaged image of the imaged substrate, and the substrate transporting mechanism transports the substrate to the processing unit based on the determined shape of the substrate (see e.g., Patent Document 1). For example, Japanese Laid-Open Patent Publication No. 2017-69386 is referred to.

However, the conventional example having such a configuration has the following problems.

That is, in the conventional device, an imaged image obtained by the imaging means imaging the substrate held by the cassette is affected by reflected light from the front surface of the substrate or multiple reflection between the substrates, or is affected by the color of the cassette appearing behind the substrate or an installed object behind the cassette appearing in the transparent portion of the cassette, and thus it is difficult to obtain an appropriate contrast at the boundary between the shape of the substrate and the background. Therefore, when the substrate transporting device transports the substrate out from the cassette, the substrate transporting device may interfere with the substrate, come into contact with the front surface of the substrate and damage the substrate, or may break the substrate.

### SUMMARY OF THE INVENTION

The present invention has been made in view of such circumstances, and an object of the present invention is to provide a substrate transporting device capable of preventing breakage of a substrate and a substrate processing device equipped with the same.

In order to achieve such an object, the present invention has the following configuration.

That is, there is provided a substrate transporting device for transporting a substrate with a carrier capable of stacking and accommodating a plurality of substrates with a gap and having a carry-in/out port on one side surface, the device including a transporting unit including a holding hand that holds the substrate, the transporting unit being configured to transport the substrate by advancing/retreating the holding hand to/from the carry-in/out port of the carrier to the gap between the substrates; an acquisition unit configured to acquire shape information of the substrate when the substrate is viewed in an advancing/retreating direction of the holding hand and from a carry-in/out port side of the carrier in a state where the substrate is accommodated in the carrier; and a control unit configured to control the transporting unit based on the shape information, in which the acquisition unit obtains the shape information of the substrate by irradiating light in a wavelength region longer than visible light from the advancing/retreating direction of the holding hand.

According to the substrate transporting device of the present invention, the shape information of the substrate used to control the transporting unit is the shape information when the substrate is viewed from the carry-in/out port side of the carrier in the advancing/retreating direction of the holding hand, and is the shape information obtained by irradiating the substrate with light in a wavelength region longer than visible light from the advancing/retreating direction of the holding hand, thereby making the substrate less susceptible to the influence of reflected light from the front surface of the substrate, the influence of multiple reflection between the substrates, and the influence of an object appearing behind the substrate. Therefore, an appropriate contrast can be obtained at the boundary between the shape of the substrate and the background, and breakage of the substrate can be prevented.

Furthermore, in the substrate transporting device according to the present invention, the light in the wavelength region longer than the visible light is preferably light in a wavelength region that transmits through the inside of the substrate. This makes it possible to remove the influence of reflected light from the front surface of the substrate, the influence of multiple reflection between the substrates, and the influence of an object appearing behind the substrate.

Furthermore, in the substrate transporting device according to the present invention, the light in the wavelength region longer than the visible light is preferably light in a near-infrared wavelength region. This makes it possible to remove the influence of reflected light from the front surface of the substrate, the influence of multiple reflection between the substrates, and the influence of an object appearing behind the substrate.

Furthermore, in the substrate transporting device according to the present invention, the shape information is preferably a cross-sectional shape of the substrate at a predetermined position in an advancing/retreating direction of the holding hand. As a result, the three-dimensional shape of the substrate at a predetermined position in the advancing/retreating direction of the holding hand can be grasped.

In addition, in the substrate transporting device according to the present invention, the predetermined position of the substrate in the depth direction is preferably a central portion of the substrate accommodated in the carrier. As a result, a place where the warpage or thickness of the substrate accommodated in the carrier tends to become large can be grasped.

Furthermore, in the substrate transporting device according to the present invention, the shape information preferably includes the shape of the upper edge portion of the substrate accommodated in the carrier. As a result, the shape of the substrate accommodated in the carrier can be three-dimensionally grasped by the central portion and the upper edge portion.

Furthermore, in the substrate transporting device according to the present invention, the acquisition unit preferably includes an imaging unit configured to image the substrate accommodated in the carrier using light in a wavelength region longer than the visible light and acquire a substrate image, and acquire the shape information from the substrate image. As a result, a substrate image in which the influence of reflected light from the front surface of the substrate, the influence of multiple reflection between the substrates, and the influence of an object appearing behind the substrate are small can be acquired.

Moreover, in the substrate transporting device according to the present invention, the imaging unit is preferably included in the transporting unit. As a result, the imaging position of the imaging unit and the order of imaging can be freely adjusted.

Furthermore, in the substrate transporting device according to the present invention, preferably, a placement portion on which the carrier is placed; and an opening mechanism configured to open a door of the carrier placed on the placement portion are further provided; in which the imaging unit images the substrate in a state in which the opening mechanism has opened the door or in a process of the opening mechanism opening the door. As a result, the shape information of the substrate immediately before being transported to the transporting unit can be accurately acquired.

Furthermore, in the substrate transporting device according to the present invention, the imaging unit is preferably included in the opening mechanism. Thus, the transporting unit can be simply configured without including the imaging unit.

In addition, in the substrate transporting device according to the present invention, a gap information acquisition unit configured to acquire gap information between the substrates into which the transporting unit advances based on the shape information of the plurality of substrates accommodated in the carrier is further preferably provided; in which the control unit controls the transporting unit based on the gap information. As a result, gap information that is less susceptible to the influence of reflected light from the front surface of the substrate, the influence of multiple reflection between the substrates, and the influence of an object appearing behind the substrate can be acquired.

Furthermore, in the substrate transporting device according to the present invention, the control unit preferably adjusts the insertion height position of the holding hand based on the gap information. Thus, breakage of the substrate can be effectively prevented.

In order to achieve such an object, the present invention has the following configuration.

That is, a substrate processing device includes a substrate transporting device for transporting a substrate with a carrier capable of stacking and accommodating a plurality of substrates with a gap and having a carry-in/out port on one side surface; a processing unit configured to perform a predetermined process on a substrate transported by the substrate transporting device; a transporting unit including a holding hand that holds the substrate, the transporting unit being configured to transport the substrate by advancing/retreating the holding hand to/from the carry-in/out port of the carrier to the gap between the substrates; an acquisition unit configured to acquire shape information of the substrate when the substrate is viewed in an advancing/retreating direction of the holding hand and from a carry-in/out port side of the carrier in a state where the substrate is accommodated in the carrier; and a control unit configured to control the transporting unit based on the shape information; in which the acquisition unit obtains the shape information of the substrate by irradiating light in a wavelength region longer than visible light from the advancing/retreating direction of the holding hand. As a result, the substrate can be processed without breaking the substrate.

### BRIEF DESCRIPTION OF THE DRAWINGS

For the purpose of illustrating the invention, there are shown in the drawings several forms which are presently preferred, it being understood, however, that the invention is not limited to the precise arrangement and instrumentalities shown.

FIG. 1 is a plan view illustrating an overall configuration of a substrate processing device according to a first example;

FIGS. 2A to 2E are side views illustrating the configuration and operation of a carry-in/out block;

FIG. 3A is a view for describing an imaging unit, and FIG. 3B is a view for describing an imaging method of a substrate accommodated in a carrier;

FIG. 4 is a plan view schematically illustrating a substrate and an imaging unit;

FIGS. 5A and 5B are views illustrating an example of a bowl shaped warped substrate, where FIG. 5A is a view as viewed from the front-back direction X, and FIG. 5B is a view as viewed from the width direction Y;

FIGS. 6A to 6C are views illustrating a principle of acquiring a near-infrared image of the lower edge portion W of the substrate;

FIG. 7A is a front view illustrating a part of the substrate accommodated in the carrier, and FIG. 7B is a view illustrating the near-infrared image;

FIG. 8 is a block diagram illustrating an example of a control system;

FIGS. 9A to 9C are views conceptually illustrating a method of obtaining the inter-substrate gap information using the infrared image;

FIGS. 10A and 10B are diagrams conceptually illustrating a method of obtaining an inter-substrate center position;

FIGS. 11A and 11B are diagrams illustrating an example of a substrate warped in an umbrella shape, where FIG. 11A is a view as viewed from the front-back direction X, and FIG. 11B is a view as viewed from the width direction Y;

FIGS. 12A and 12B are diagrams illustrating an example of a substrate warped in a half-pipe shape, where FIG. 12A is a view as viewed from the front-back direction X, and FIG. 12B is a view as viewed from the width direction Y;

FIGS. 13A and 13B are diagrams illustrating an arrangement of the imaging unit according to a modified example;

FIGS. 14A and 14B are diagrams illustrating a method of imaging a substrate according to a modified example; and

FIGS. 15A and 15B are diagrams illustrating a method of imaging a substrate according to a modified example different from that in FIG. 14.

### DESCRIPTION OF THE PREFERRED EMBODIMENTS

Hereinafter, preferred examples of the present invention will be described in detail with reference to the drawings.

### Detailed Description

Hereinafter, the present invention will be described with reference to various preferred examples.

### First Example

Hereinafter, a first example of the present invention will be described with reference to the drawings.

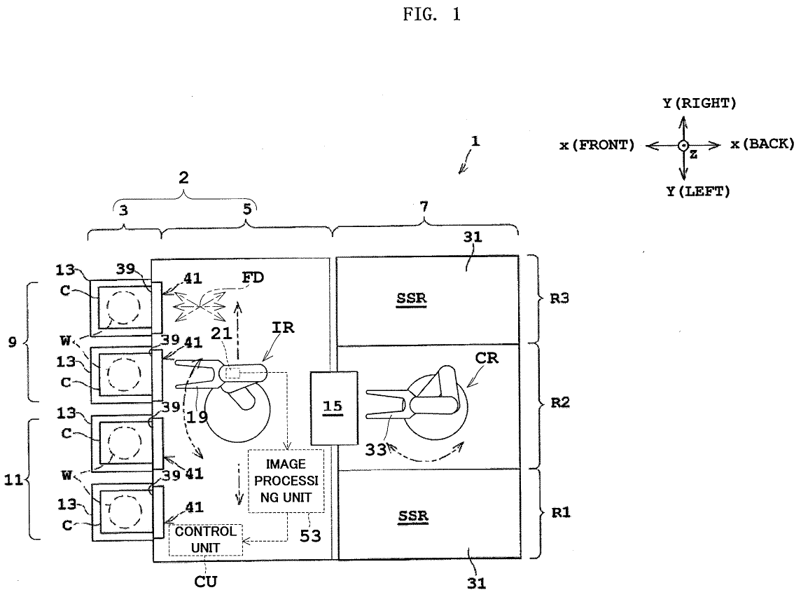

FIG. 1 is a plan view illustrating an overall configuration of a substrate transporting device 2 according to a first example and a substrate processing device 1 equipped with the same.

### <1. Overall Configuration>

The substrate processing device 1 includes a carry-in/out block 3, an indexer block 5, and a processing block 7. The carry-in/out block 3 and the indexer block 5 form the substrate transporting device 2.

The substrate processing device 1 processes a substrate W. The substrate W has, for example, a circular shape in plan view. The substrate processing device 1 performs, for example, washing process on the substrate W. The substrate processing device 1 processes the substrate W in a single wafer processing in the processing block 7. In the single wafer processing, one substrate W is processed one by one in a state of a horizontal posture.

In the present specification, for the sake of convenience, a direction in which the carry-in/out block 3, the indexer block 5, and the processing block 7 are arranged is referred to as a “front-back direction X”. The front-back direction X is horizontal. Of the front-back direction X, the direction from the processing block 7 toward the carry-in/out block 3 is referred to as “front side”. A direction opposite to the front side is referred to as “back side”. A horizontal direction orthogonal to the front-back direction X is referred to as a “width direction Y”. One direction in the “width direction Y” is appropriately referred to as a “right side”. A direction opposite to the right side is referred to as “left side”. A direction perpendicular to the horizontal direction is referred to as a “vertical direction Z”. In each drawing, front, back, right, left, top, and bottom are appropriately shown for reference.

### <2. Carry-In/Out Block>

The carry-in/out block 3 includes an input unit 9 and a dispensing unit 11. The input unit 9 and the dispensing unit 11 are arranged in the width direction Y. A plurality of (e.g., 25) substrates W are stacked and stored in one carrier C at constant intervals in a horizontal posture. The carrier C storing the unprocessed substrate W is placed on the input unit 9. The input unit 9 includes, for example, two placement tables 13 on which the carrier C is placed. The carrier C separates the surfaces of the substrates W from each other and accommodates the substrates W one by one. The carrier C accommodates the substrates, for example, in a posture in which the front surface of the substrate W is facing upward. As the carrier C, for example, there is a front opening unify pod (FOUP). The FOUP is a sealed container. The carrier C may be an open type container and may be of any type.

The dispensing unit 11 is disposed on the opposite side of the input unit 9 with the central portion in the width direction Y of the substrate processing device 1 in between. The dispensing unit 11 is disposed on the left side Y of the input unit 9. The dispensing unit 11 stores the processed substrate W in the carrier C and dispenses the processed substrate W by the carrier C. Similarly to the input unit 9, the dispensing unit 11 functioning in this manner includes, for example, two placement tables 13 for placing the carrier C. The input unit 9 and the dispensing unit 11 are also called load ports.

### <3. Indexer Block>

The indexer block 5 is disposed adjacent to the back side X of the carry-in/out block 3 in the substrate processing device 1. The indexer block 5 includes an indexer robot IR and a delivery unit 15.

The indexer robot IR is configured to be rotatable about the vertical direction Z. The indexer robot IR is configured to be movable in the width direction Y. The indexer robot IR includes a hand 19. The hand 19 holds one substrate W. The hand 19 is configured to advance and retreat independently in the front-back direction X. The indexer robot IR moves in the width direction Y and rotates about the vertical direction Z. The indexer robot IR advances/retreats the hand 19 to deliver the substrate W between the cassette C and the delivery unit 15. A direction in which the hand 19 moves when delivering the substrate W to/from the carrier C is defined as an advancing/retreating direction FD.

The advancing/retreating direction FD is indicated by one arrow indicating the front-back direction X and two arrows indicating oblique directions with respect to the front-back direction X. The arrow indicating the oblique direction may be shifted from the illustrated oblique direction as long as the arrow is oblique with respect to the front-back direction X. The advancing/retreating direction FD may include a component in the width direction Y or the vertical direction Z as long as the component is in the direction in which the hand 19 moves.

In addition, the substrate transporting device 2 controls the indexer robot IR based on the shape information of the substrate W. The shape information of the substrate W is obtained by using near-infrared rays. The shape information of the substrate W includes at least shape information at a predetermined position in the depth direction of the substrate W accommodated in the carrier C. The shape information of the substrate W is acquired, for example, in the indexer block 5. The indexer block 5 includes an imaging unit 21. The imaging unit 21 images the substrate W accommodated in the carrier C by emitting near-infrared rays from the advancing/retreating direction FD of the carrier C. The imaging unit 21 acquires an image of the substrate W accommodated in the carrier C. The imaging unit 21 is provided in, for example, the indexer robot IR.

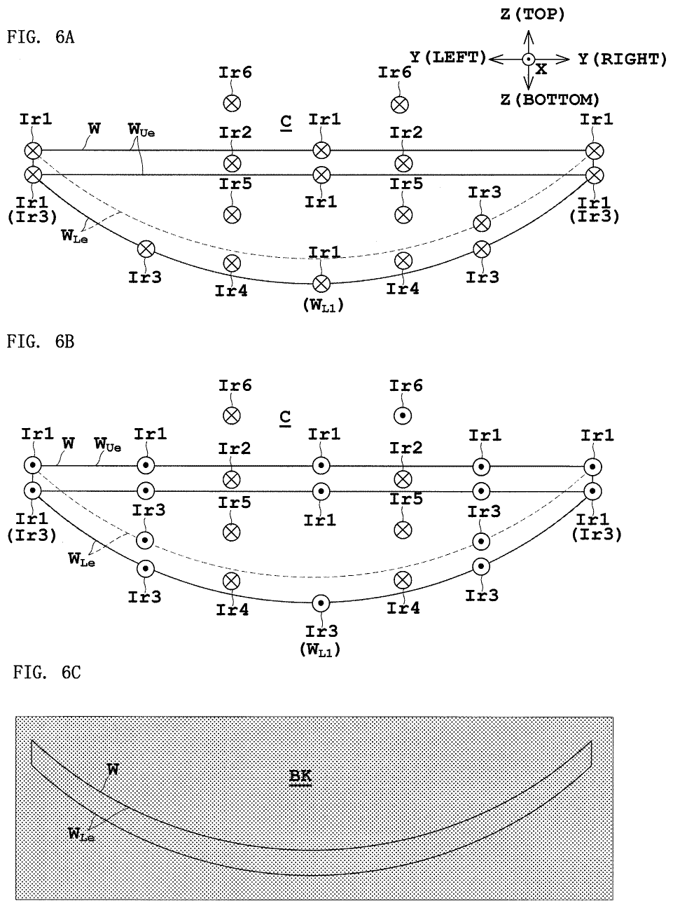

Here, the near-infrared ray is roughly an infrared ray included in a wavelength region shorter than the wavelength region of the far infrared ray in the wavelength region of the infrared ray. That is, the infrared ray is an electromagnetic wave in a wavelength range of up to about 1 mm with the upper limit of visible light of 0.76 to 0.8 μm as a lower limit. The near-infrared rays are infrared rays having a wavelength of less than or equal to 2.5 μm in the wavelength region of the infrared ray. The near-infrared ray in the present invention is preferably a wavelength region capable of acquiring a near-infrared image in which the shape of the substrate W and the carrier C behind the substrate W can be clearly distinguished. It is preferable that the near-infrared rays be reflected by the edge portion of the substrate W, transmitted through the inside of the substrate W, and have a near-infrared ray transmittance lower than that of the substrate W with respect to the carrier C formed of a synthetic resin. In the present invention, the edge portion corresponds to the outermost periphery of the substrate W when the substrate W accommodated in the carrier C is viewed from the opening of the carrier C. In the case of the substrate W whose center is convex downward, the upper edge portion Wᵤₑ and the lower edge portion W_{Le} in FIG. 6 correspond to the edge portions. The edge portion is an interface between the substrate W and the atmosphere, and a refractive index difference is generated between the substrate W and the atmosphere. Therefore, when light enters the edge portion, the light is reflected. Furthermore, in the present invention, the inside corresponds to a portion other than the edge portion when the substrate W accommodated in the carrier C is viewed from the opening of the carrier C.

The delivery unit 15 is disposed at a boundary with the processing block 7 in the indexer block 5. The delivery unit 15 is disposed, for example, at a central portion in the width direction Y. The delivery unit 15 includes an inverting unit (not illustrated) that reverses the substrate W upside down.

### <4. Processing Block>

The processing block 7 performs, for example, washing process on the substrate W. The washing process is, for example, a process that uses a brush in addition to the processing liquid. As illustrated in FIG. 1, for example, the processing block 7 is divided into a first row R1, a second row R2, and a third row R3 in the width direction Y. Specifically, the first row R1 is arranged on the left side Y. The second row R2 is arranged at the central portion in the width direction Y. In other words, the second row R2 is arranged on the right side Y of the first row R1. The third row R3 is arranged on the right side Y of the second row R2.

The processing block 7 is configured as described above. Here, an operation example of the center robot CR will be briefly described. The center robot CR receives the substrate W from the delivery unit 15. The center robot CR transports the substrate W to the back surface washing unit SSR in either the first row R1 and the third row R3. The back surface washing unit SSR performs washing process on the back surface of the transported substrate W. The center robot CR receives the substrate W subjected to the washing process in the back surface washing unit SSR in either the first row R1 and the third row R. The center robot CR transports the substrate W to the delivery unit 15.

### <5. Placement Table>

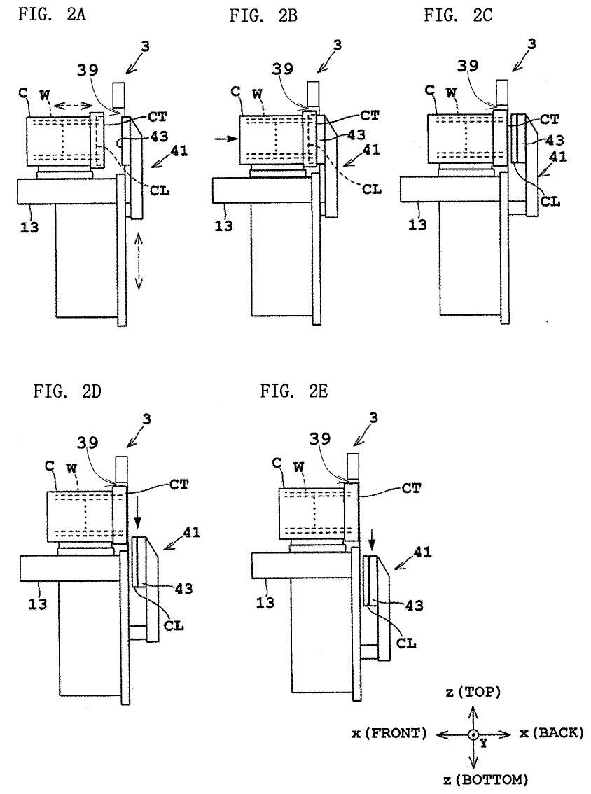

Here, the above-described carry-in/out block 3 will be described in detail with reference to FIGS. 1 and 2. FIGS. 2A to 2E are side views illustrating the configuration and operation of the carry-in/out block.

The carry-in/out block 3 includes a placement table 13, an opening 39, and a lid opening/closing mechanism 41. The carrier C is placed on the placement table 13. The placement table 13 includes a mechanism (not illustrated) that moves the carrier C in the front-back direction X. The placement table 13 can advance/retreat the carrier C with respect to the opening 39. The carrier C has a carry-in/out port CT. The carry-in/out port CT is formed on one side surface of the carrier C. The plurality of substrates W stacked and accommodated in the carrier C are carried in/out via the carry-in/out port CT. The carrier C includes a lid CL. The lid CL is configured to be freely attached and detached to/from the carry-in/out port CT of the carrier C. The lid CL seals the inside of the carrier C. When the lid CL is mounted to the carrier C, the atmosphere with the outside of the carrier C is shielded.

The lid opening/closing mechanism 41 includes an attachment/detachment unit 43 on the front side X. The attachment/detachment unit 43 detaches the lid CL from the carrier C and attaches the lid CL to the carrier C. The attachment/detachment unit 43 is movable in the vertical direction Z and the front-back direction X while holding the lid CL. The lid opening/closing mechanism 41 is movable in the front-back direction X at the opening 39 in a state of holding the lid CL. The lid opening/closing mechanism 41 can be moved up and down in the vertical direction Z in a state of holding the lid CL. The lid opening/closing mechanism 41 can move downward in the vertical direction Z from the opening 39 in a state of holding the lid CL. The lid opening/closing mechanism 41 can fully open the opening 39 by lowering in a state of holding the lid CL.

First, as illustrated in FIG. 2A, the carrier C is placed on the placement table 13. A plurality of substrates W are stacked and accommodated in the carrier C, and closed by the lid CL. At this time, the lid opening/closing mechanism 41 locates the attachment/detachment unit 43 in the opening 39. Accordingly, the inside of the indexer block 5 is separated from the external atmosphere.

As illustrated in FIG. 2B, the placement table 13 moves the carrier C to the back side X. In the carrier C, the carry-in/out port CT and the lid CL are located in the opening 39. At this time, the attachment/detachment unit 43 unlocks the lid CL and holds the lid CL. The holding is performed, for example, by the attachment/detachment unit 43 adsorbing the lid CL.

As illustrated in FIG. 2C, the lid opening/closing mechanism 41 moves to the back side X. Thus, the lid CL is moved from the opening 39 to the back side X. The lid CL is moved to the inside of the indexer block 5.

As illustrated in FIG. 2D, the lid opening/closing mechanism 41 moves downward in the vertical direction Z. The lid opening/closing mechanism 41 lowers the attachment/detachment unit 43 to the lower part of the carry-in/out port CT. The lid opening/closing mechanism 41 lowers the attachment/detachment unit 43 until the upper part of the attachment/detachment unit 43 is located at the lower part of the opening 39.

As illustrated in FIG. 2E, the lid opening/closing mechanism 41 moves the attachment/detachment unit 43 to the lowermost part. The lid opening/closing mechanism 41 lowers the attachment/detachment unit 43 to a position where the attachment/detachment unit 43 does not overlap the opening 39 in the front-back direction X. As a result, the opening 39 is fully opened. The plurality of substrates W in the carrier C can face the indexer block 5 through the opening 39.

### <6. Configuration of Imaging Unit and Carrier C>

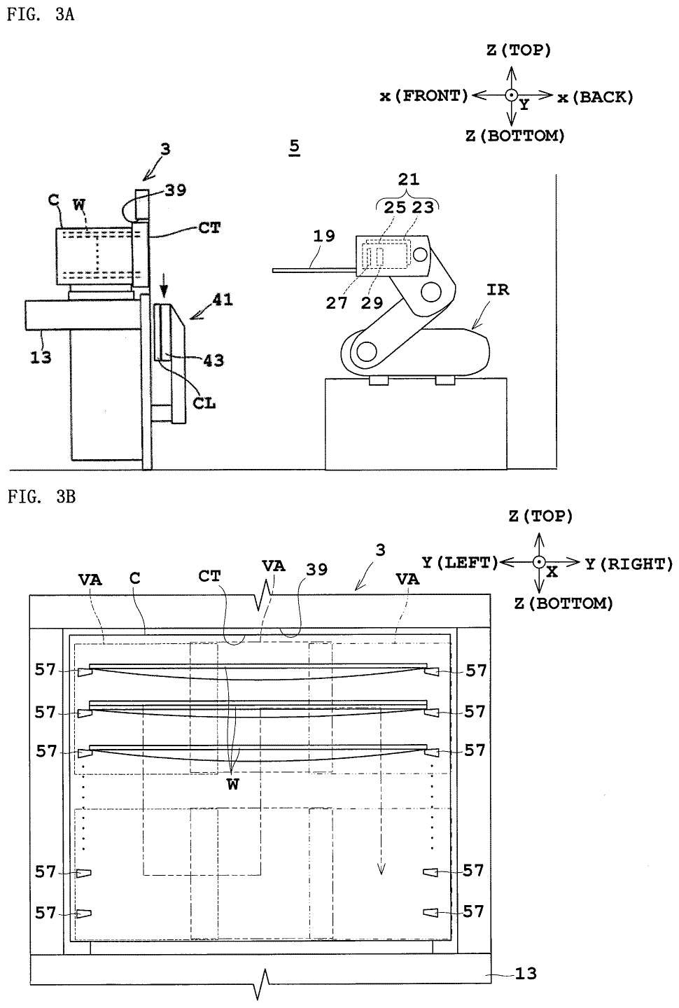

Refer to FIG. 3. FIG. 3A is a view for describing the imaging unit 21, and FIG. 3B is a view for describing an imaging method of the substrate W accommodated in the carrier C.

As illustrated in FIG. 3A, the imaging unit 21 is provided in the indexer block 5. The imaging unit 21 is provided in, for example, the indexer robot IR.

The imaging unit 21 includes a near-infrared irradiation unit 23 and a near-infrared camera 25. The near-infrared irradiation unit 23 irradiates the substrate W with near-infrared rays. The near-infrared camera 25 images the substrate W accommodated in the carrier C using near-infrared rays reflected from the substrate W accommodated in the carrier C. The near-infrared camera 25 includes a lens 27 and an imaging sensor 29. The lens 27 transmits near-infrared rays from incident light. The imaging sensor 29 converts the incident near-infrared rays into an electric signal. The lens 27 inhibits visible light from entering the imaging sensor 29 during imaging.

The imaging unit 21 images the substrate W accommodated in the carrier C using the near-infrared rays in a state where the substrate W faces the indexer block 5 through the opening 39. The imaging unit 21 acquires a near-infrared image of the substrate W accommodated in the carrier C. In the first example, the imaging unit 21 images the substrate W accommodated in the carrier C in a state where the opening 39 of the carrier C is fully opened. The imaging unit 21 may image the substrate W accommodated in the carrier C while moving the lid opening/closing mechanism 41 downward in the vertical direction Z.

As illustrated in FIG. 3B, the imaging unit 21 images, for example, three images of, for example, 25 substrates W accommodated in the carrier C. At that time, the imaging unit 21 images the substrate W by dividing the substrate W into, for example, three regions of left, middle, and right in accordance with the width of each of the field ranges VA indicated by three types of two-dot chain lines in the drawing. A near-infrared image of one substrate W is completed by superimposing the acquired three near-infrared images. For example, the imaging unit 21 is moved by the indexer robot IR in the order of the upper left, the lower left, the lower center, the upper center, the upper right, and the lower right of the opening 39. The imaging unit 21 images the substrate W accommodated in the carrier C at each position. Specifically, in a case where the imaging unit 21 images the substrates W in the first to third rows in the first imaging in the upper left field range VA, the imaging unit 21 images the substrates W in the third to fifth rows in the imaging in the next field range VA. This is because the gap between the substrates W is calculated from the acquired near-infrared image.

Note that, in a case where the field range VA has a size including the entire three substrates W, the imaging unit 21 can image the near-infrared images of the three substrates W in one imaging. In this case, the imaging unit 21 can acquire all the near-infrared images of the substrate W accommodated in the carrier C only by moving the indexer robot IR from the top to the bottom.

The carrier C is a box shaped resin molded article surrounded by a bottom surface, both side surfaces, a top surface, and a back surface. In the drawing, the carrier C has the carry-in/out port CT opened. The carrier C is formed of, for example, a synthetic resin. The synthetic resin is a transparent or translucent resin. The transparent synthetic resin is, for example, a colored transparent resin such as orange or a colorless transparent resin. The carrier C may have, for example, all the surfaces formed of a transparent resin, or only the back surface formed of a transparent resin. The synthetic resin has a lower near-infrared ray transmittance than the substrate W. Therefore, a difference between the substrate W and the back surface of the carrier C clearly appears in the near-infrared image of the substrate W accommodated in the carrier C. In other words, in the near-infrared image of the substrate W accommodated in the carrier C, an appropriate contrast is obtained at the boundary between the substrate W and the background.

### <7. Imaging of Substrate W>

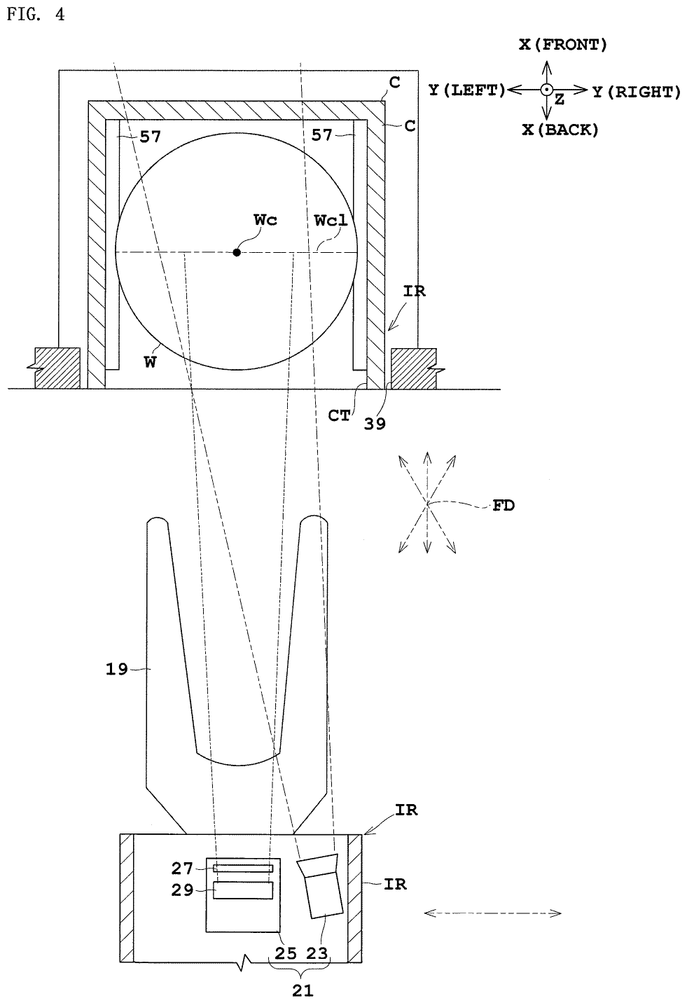

Reference is now made to FIG. 4. FIG. 4 is a plan view schematically illustrating a state in which the imaging unit images the substrate W. Note that, for the sake of convenience of description, the carrier C and an upper portion of the indexer robot IR are illustrated in cross sections.

FIG. 4 shows a state in which the substrate W faces the indexer block 5 through the opening 39. The imaging place of the substrate W is a central portion of the substrate W. The central portion of the substrate W falls within the field range of the near-infrared camera 25. The near-infrared irradiation unit 23 irradiates a range wider than the field range of the near-infrared camera 25 with near-infrared rays. The near-infrared camera 25 is provided in the vicinity of the hand 19, in other words, at the periphery of the hand 19. In the present example, the center of the near-infrared camera 25 in the width direction Y is aligned with the center of the hand 19 in the width direction Y. The near-infrared irradiation unit 23 is provided in the vicinity of the near-infrared camera 25, in other words, at the periphery of the near-infrared camera 25. The irradiation direction of the main light beam of the near-infrared ray is an advancing/retreating direction FD in an oblique direction with respect to the front-back direction X among the advancing/retreating directions FD indicated by the three arrows.

The image of the substrate W accommodated in the carrier C is photographed with the focus of the near-infrared camera 25 set to the center position Wc in the depth direction of the substrate W so as to include shape information at the center position Wc in the depth direction (front-back direction X) of the substrate W accommodated in the carrier C. The center position Wc is also the center position of the substrate W in the width direction Y. In the drawing, a one dot chain line passing through the center position Wc and drawn along the width direction Y is illustrated. This one dot chain line is referred to as a substrate center line Wcl. The near-infrared image of the substrate W accommodated in the carrier C is a tomographic image at the substrate center line Wcl. In this case, the central portion of the substrate W in the near-infrared image indicates a region including at least the center (center position Wc) of the substrate W in plan view. The central portion may be determined based on the diameter of the substrate W. In the case of the substrate W having a diameter of 300 mm, for example, a range having a diameter of 150 mm centered on the center position Wc which is a half region of the diameter may be set as the central portion. In the curved substrate W, it is considered that the most convex or concave place on the substrate is often near the center position Wc of the substrate W. Therefore, it is possible to measure the most convex or concave place on the substrate W by acquiring the tomographic image in the center part. In addition, the most convex or concave place on the substrate W does not necessarily coincide with the center position Wc. Even when they do not coincide with each other, the tomographic image of the substrate W can be suitably acquired by measuring the center part of the substrate W.

### <8. Warpage of Substrate W>

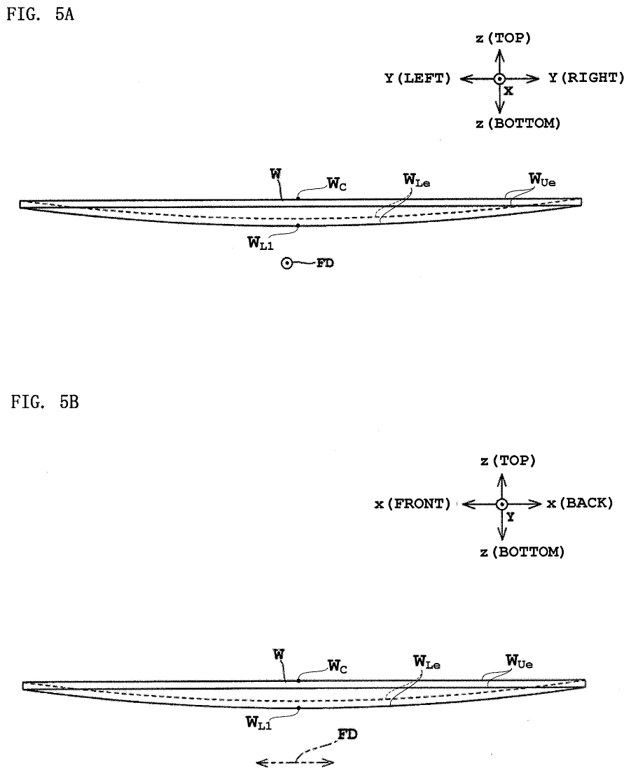

Reference is now made to FIG. 5. FIGS. 5A and 5B are examples of the bowl shaped warped substrate, where FIG. 5A is a view as viewed from the front-back direction X, and FIG. 5B is a view as viewed from the width direction Y.

The substrate W is subjected to various treatments, coated with films having different thermal expansion coefficients, and further subjected to various heat treatments. Therefore, the substrate W may be warped into a complicated shape.

FIG. 5 illustrates a substrate W warped in a bowl shape. That is, the central portion of the substrate W is recessed, and the outer peripheral edge is at a higher position than the central portion. The substrate W warped in a bowl shape in this manner has a narrow lower interval in the vertical direction Z with respect to the substrate W accommodated below such substrate W in the carrier C. FIG. 5A is a view of the substrate W as viewed from the front-back direction X. FIG. 5A is a view of the substrate W viewed from the indexer block 5 through the carry-in/out port CT. In other words, FIG. 5A is a view as viewed from the advancing/retreating direction FD of the hand 19 of the indexer robot CR toward the far side of the carrier C. FIG. 5B is a view of the substrate W as viewed from the width direction Y. FIG. 5B is a view of the substrate W viewed from the lateral direction with respect to the advancing/retreating direction FD of the hand 19. The substrate W illustrated in FIGS. 5A and 5B is convexly curved downward.

Here, the lowest place of the lowermost surface of the substrate W is referred to as a lowermost point W_{L1}. In the substrate W illustrated in FIG. 5, the lowermost point W_{L1} is located immediately below the center position W_{C}. A cross section of the substrate W passing through the lowermost point W_{L1} illustrated in FIG. 5A and extending in the width direction Y along the warpage of the substrate W is referred to as a lower edge portion W_{Le}. A solid line of the warpage of the substrate W illustrated in FIG. 5A indicates the lower side of the lower edge portion W_{Le}, and a broken line on the inner side of the warpage indicates the upper side of the lower edge portion W_{Le}. When stored in the carrier C, the lower edge portion W_{Le} exists at the same position in the depth direction as the substrate center line Wcl illustrated in FIG. 4. Furthermore, in FIG. 5, a solid line extending in the horizontal direction is referred to as an upper edge portion Wᵤₑ. The upper edge portion Wᵤₑ is an upper side and a lower side of the peripheral edge of the substrate W when viewed from the front-back direction X. In the near-infrared image of the substrate W accommodated in the carrier C, the substrate center line Wcl is the focusing position of the near-infrared camera 25. Therefore, the lower edge portion W_{Le}, which is a tomographic image of the substrate W at the substrate center line Wcl, is acquired as a near-infrared image of the substrate W.

### <9. Principle of Acquiring Near-Infrared Image of Lower Edge Portion of Substrate>

FIG. 6 is a view illustrating a principle of acquiring a near-infrared image of the lower edge portion W_{Le} of the substrate W accommodated in the carrier C. FIGS. 6A and 6B are front views of the substrate W accommodated in the carrier C. FIG. 6C is an acquired near-infrared image. Note that a place indicated by a solid line in the substrate W is an outer peripheral edge of the substrate W visible with visible light when the substrate W is viewed from the front-back direction X. A place indicated by a broken line is an upper side of the substrate W in a virtual cross section at the center position Wc when the substrate W is viewed from the front-back direction X.

FIG. 6A illustrates a state in which near-infrared rays are emitted from the near-infrared irradiation unit 23. For the sake of convenience of description, the field range VA is assumed as the entire substrate W. Furthermore, for the sake of convenience of illustration, near-infrared rays are illustrated as being emitted from the front of the substrate W. That is, in FIGS. 6A and 6B, a representative place irradiated with the near-infrared rays in the substrate W is indicated by a circled X mark. The direction in which the near-infrared ray is emitted indicated by the circled X mark is the front side in the front-back direction X. On the other hand, in FIG. 6B, a place where the near-infrared rays are reflected from a representative place of the substrate W irradiated with the near-infrared rays is indicated by a circled black circle. The direction in which the near-infrared rays is reflected indicated by the circled black circle is the back side in the front-back direction X. Reference signs Ir1 to Ir6 denote near-infrared rays emitted from the near-infrared irradiation unit 23. Ir1 is a near-infrared ray emitted to the upper edge portion Wᵤₑ of the substrate W. Ir2 is a near-infrared ray emitted to the inside of the upper edge which is the inner side of the upper edge portion Wᵤₑ. Ir3 is a near-infrared ray emitted to the lower edge portion W_{Le} along the width direction Y passing through the lowermost point W_{L1} of the substrate W. Ir4 is a near-infrared ray emitted to the inside of the lower edge which is the inner side of the lower edge portion W_{Le}. Ir5 is a near-infrared ray emitted to other places of the substrate W. Ir6 is a near-infrared ray emitted to the cassette C located behind the substrate W.

FIG. 6B illustrates a state in which near-infrared rays emitted from the near-infrared irradiation unit 23 are reflected from the substrate W and the carrier C. Specifically, the near-infrared rays Ir1 and Ir3 emitted to the upper edge portion Wᵤₑ and the lower edge portion W_{Le} are reflected by the upper edge portion Wᵤₑ and the lower edge portion W_{Le}. The near-infrared rays Ir2, Ir4, and Ir5 emitted to the inside of the upper edge, the inside of the lower edge, and other places of the substrate W transmit through the inside of the substrate W. Regarding the near-infrared rays Ir6 emitted to the cassette C located behind the substrate W, in relation to the material of the carrier C, the near-infrared rays in some wavelength regions are transmitted through the cassette C or absorbed by the cassette C, but the near-infrared rays in other wavelength regions are reflected by the cassette C.

FIG. 6C is an image of the substrate W accommodated in the carrier C imaged by the near-infrared camera 25. This image includes the lower edge portion W_{Le} of the substrate W and a uniform background BK except for the lower edge portion W_{Le}. The inside of the lower edge is a background BK. The image of the lower edge portion W_{Le} corresponds to the contour shape of the cross section of the lower edge portion W_{Le} of the substrate W. The upper edge portion Wᵤₑ is not shown in this image. When the image is photographed, the near-infrared camera does not focus on the upper edge portion Wᵤₑ, but focuses on the center position Wc of the substrate W in the depth direction. In the case of the present example, no upper edge portion Wᵤₑ exists in the substrate W at the center position Wc. Therefore, the carrier C located in the background of the substrate W is shown as a uniform background BK in a place other than the lower edge portion W_{Le} of the substrate W. The image of the lower edge portion W_{Le} is displayed in black. The image of the background BK is uniformly displayed in gray lighter than black. Therefore, the computer can clearly identify the lower edge portion W_{Le} of the substrate W from the background BK by image processing.

### <10. Near-Infrared Image>

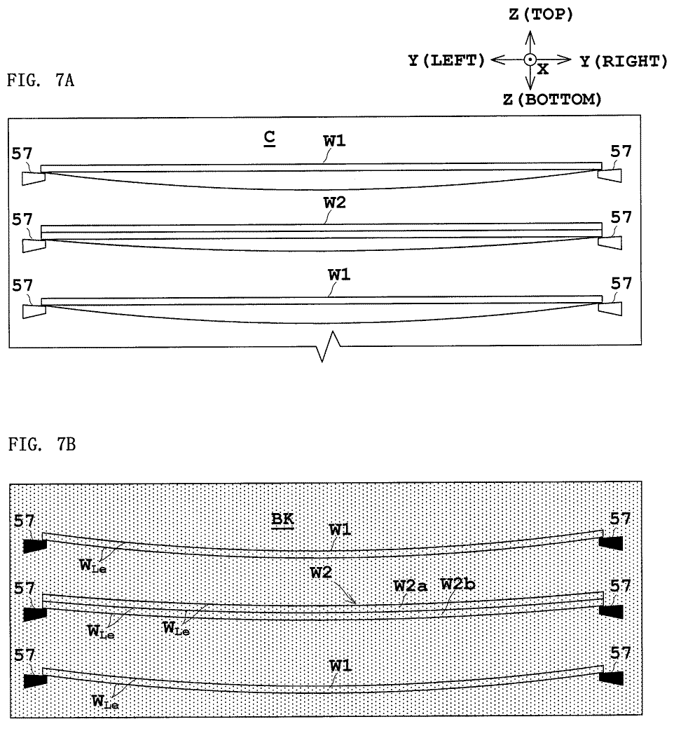

FIG. 7A is a view illustrating the substrate W accommodated in the carrier C included in the field range VA of the near-infrared camera 25. FIG. 7B is a view illustrating a near-infrared image acquired from FIG. 7A.

FIG. 7A illustrates a state in which the substrate W is accommodated in the carrier C. The substrate W is accommodated in a state where the left end portion and the right end portion of the peripheral edge portion are placed on a locking portions 57 attached to the left and right side surfaces of the carrier C. FIG. 7A illustrates three substrates W from the top of the carrier C. The field range VA of the near-infrared camera 25 includes three substrates W accommodated in the carrier C. The substrates W in the upper and lower stages are warped. Hereinafter, the substrates W on the upper and lower stages are referred to as warped substrates W1. The substrate W in the middle stage is a substrate W obtained by laminating the two substrates W. Hereinafter, the substrate W in the middle stage is referred to as a laminated substrate W2. The laminated substrate W2 is also warped. The magnitude of warpage varies depending on the substrate W. If the warped substrate W1 and the laminated substrate W2 are photographed with visible light beam, the visible light image is affected by the reflection of the upper and lower substrates W and the background BK appearing behind the carrier C. Therefore, it is difficult for a computer to accurately measure the shapes of the warped substrate W1 and the laminated substrate W2 by image processing and accurately acquire gap information between the substrates W.

As illustrated in FIG. 7B, in the near-infrared image, reflected light (visible light) from the upper and lower substrates W is cut by the lens 27 and thus does not appear. In addition, in the near-infrared image, since the uniformly opaque gray background BK is displayed behind the warped substrate W1 and the laminated substrate W2, an object located behind the carrier C does not appear. Furthermore, in the laminated substrate W2, the boundary of the respective lower edge portions W_{Le} of the laminated substrates W2a and W2b is also clearly shown. Therefore, the computer can accurately measure the shapes of the warped substrate W1 and the laminated substrate W2 by image processing, and can accurately acquire gap information between the substrates W.

### <11. Control System>

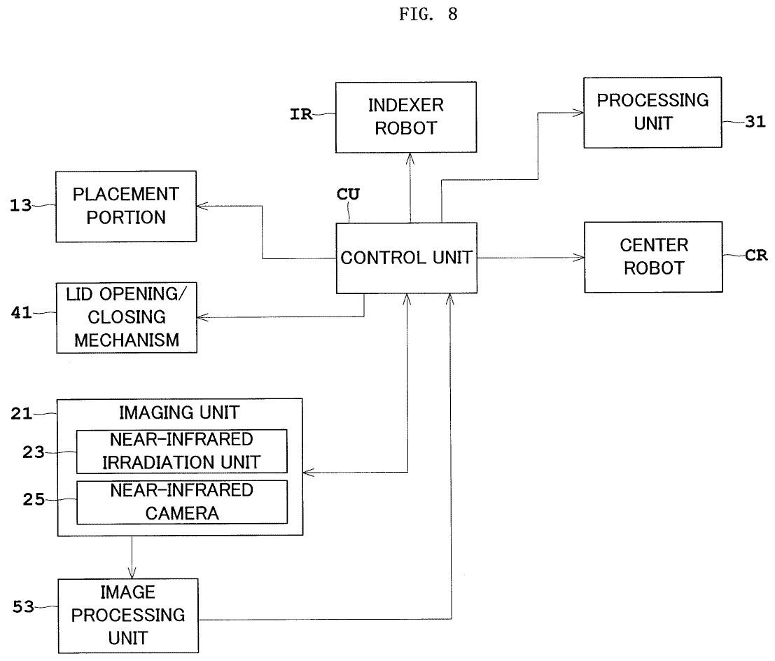

FIG. 8 is a block diagram illustrating an example of a control system of the substrate processing device 1 illustrated in FIG. 1.

The substrate processing device 1 is totally controlled by the control unit CU. The control unit CU includes a CPU, a memory (storage unit 51), and the like. The control unit CU operates by a program stored in advance in the storage unit 51. The control unit CU controls a mechanism (not illustrated) that moves the carrier C in the placement table 10 in the front-back direction X. The control unit CU controls the attaching and detaching operation of the lid CL by the attachment/detachment unit 43 of the lid opening/closing mechanism 41 and the raising/lowering operation of the lid opening/closing mechanism 41. When carrying out the raising/lowering operation of the lid opening//closing mechanism 41, the control unit CU carries out the raising/lowering operation while referring to the height position in the vertical direction Z output from the lid opening/closing mechanism 41. The control unit CU controls the indexer robot IR. Specifically, the control unit CU controls the movement of the hand 19 in the advancing/retreating direction FD in the indexer robot IR, the movement of the hand 19 in the vertical direction Z, and the turning of the indexer robot IR about the vertical direction Z. The control unit CU controls processing of the substrate W in the processing unit 31. The control unit CU controls the center robot CR. The control unit CU controls advancing/retreating movement of the hand 33 of the center robot CR, movement of the hand 33 in the vertical direction Z, and turning of the center robot CR about the vertical direction Z.

The control unit CU will be described in more detail. The control unit CU grasps the current position of the indexer robot IR based on a signal output from a sensor provided in each drive unit of the indexer robot IR. The control unit CU controls the indexer robot IR to locate the imaging unit 21 at the imaging start position at the timing the lid opening/closing mechanism 41 has finished lowering in the vertical direction Z. As illustrated in FIG. 3B, the control unit CU controls the imaging unit 21 and the indexer robot IR such that the imaging unit 21 sequentially acquires infrared images while moving through a plurality of imaging positions in the order of upper left, lower left, lower center, upper center, upper right, and lower right.

Each of the imaging unit 21 and the indexer robot IR also includes a control unit. The control unit included in the indexer robot drives each drive unit of the indexer robot IR based on an instruction from the control unit CU. The control unit included in the imaging unit 21 controls the near-infrared irradiation unit 23 and the near-infrared camera 25 based on an instruction from the control unit CU.

### <12. Image Processing Unit>

When the imaging unit 21 acquires the near-infrared image of the substrate W accommodated in the carrier C, the imaging unit 21 transmits the acquired near-infrared image data to the image processing unit 53. The image processing unit 53 is a computer different from the control unit CU. Note that the image processing unit 53 may be a computer same as the control unit CU. The image processing unit 53 calculates the shape of the substrate W using the near-infrared image data, and calculates an inter-substrate gap information GPw, an inter-standard substrate center position CP0, an inter-individual substrate center position CP1, a gap GP1, a gap GP2, and the like to be described later from the calculated shape of the substrate W. The image processing unit 53 transmits the calculated information to the control unit CU. The control unit CU controls the indexer robot IR based on the information received from the image processing unit 53. Specifically, the control unit CU adjusts the insertion height position of the hand 19 based on the inter-substrate gap information GPw. The control unit CU determines whether or not the hand 19 can be inserted. Hereinafter, process performed by the image processing unit 53 will be described.

### <13. Method of Obtaining Inter-Substrate Gap Information Using Near-Infrared Image>

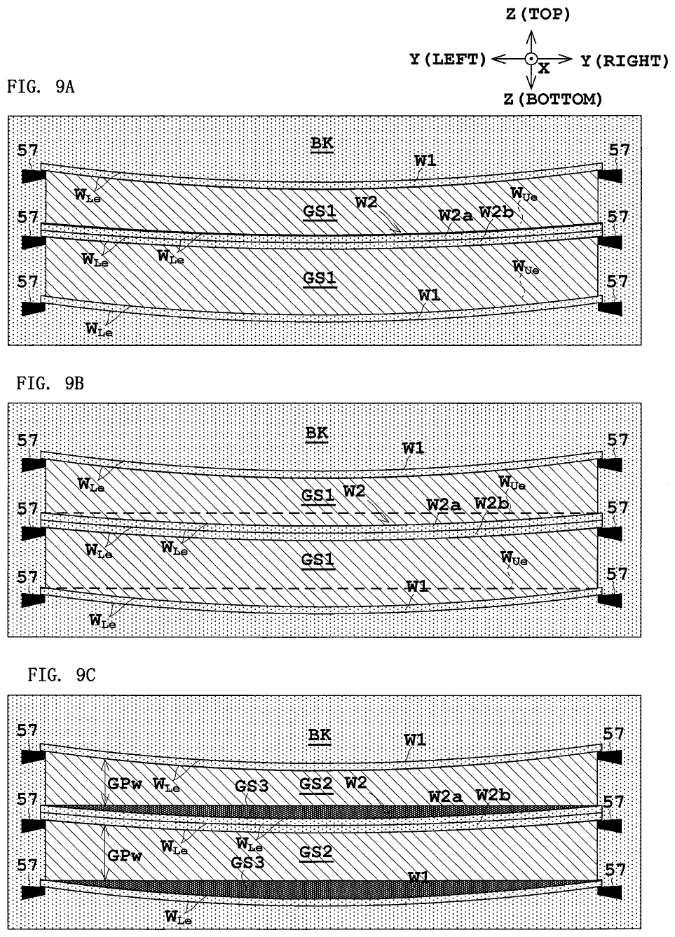

FIGS. 9A to 9C are views for explaining a method of obtaining the inter-substrate gap information GPw using the near-infrared image.

FIG. 9A is a view illustrating a formal inter-substrate gap region GS1. The inter-substrate gap region GS1 is a gap region obtained without considering the upper edge portion W_{Ue}. The formal inter-substrate gap region GS1 is calculated from a tomographic image (near-infrared image) at the substrate center line Wcl. When the tomographic image is imaged, the focusing position is set on the substrate center line Wcl, so that the upper edge portion W_{Ue} located on the near side of the focusing position on the substrate W is not image-formed. The formal inter-substrate gap region GS1 calculated from the tomographic image is a region sandwiched between the upper and lower substrates W except for a region overlapping with the locking portion 57 in the vertical direction Z. The formal inter-substrate gap region GS1 is acquired from, for example, position information of the substrate W in the vertical direction Z, thickness information of the substrate W, and shape information of warpage of the substrate W. These pieces of information are corresponded with pixels of the imaging sensor 29. A correspondence relationship between a pixel of a near-infrared image and an actual length is known.

FIG. 9B is a view illustrating a warped substrate W1, an overlapping substrate W2, and an upper edge portion W_{Ue} virtually set in the overlapping substrate W2 in a formal inter-substrate gap region GS1. The upper edge portion W_{Ue} is a line indicated by a broken line, and is a line connecting upper ends on both left and right sides of the lower edge portion W_{Le}. A line connecting upper ends on both left and right sides of the lower edge portion W_{Le} is set as a virtual upper edge portion W_{Ue}. The virtually set upper edge portion W_{Ue} corresponds to an actual upper edge portion of the substrate W2.

FIG. 9C is a view illustrating a substantial inter-substrate gap region GS2. The substantial inter-substrate gap region GS2 is a region where the hand 19 considering the actual upper edge portion of the substrate W2 cannot advance due to the virtually set upper edge portion W_{Ue}. A region from the line indicating the upper edge portion W_{Ue} to the lower edge portion W_{Le} is an advancement disabled region GS3 where the hand 19 cannot enter due to the presence of the overlapping substrate W2. The advancement disabled region GS3 is indicated by dark shading in the drawing. A region excluding the advancement disabled region GS3 from the formal inter-substrate gap region GS1 is a substantial inter-substrate gap region GS2. As a result, at any position in the width direction Y of the substantial inter-substrate gap region GS2, the length in the vertical direction Z of the substantial inter-substrate gap region GS2 can be obtained as the inter-substrate gap information GPw.

### <14. Method of Obtaining Inter-Substrate Center Position Using Near-Infrared Image>

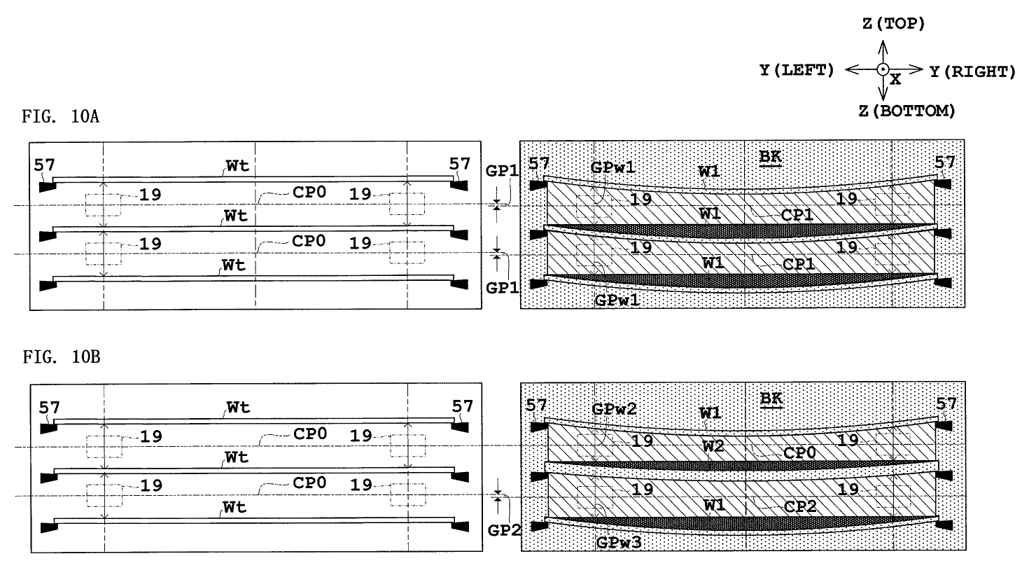

FIG. 10 is a view illustrating a method of obtaining the inter-substrate center position using the near-infrared image.

The left diagram of FIG. 10A is a diagram illustrating an inter-standard substrate center position CPO. The inter-standard substrate center position CPO indicating the height in the vertical direction Z is obtained by determining the interval between the upper and lower locking portions 57 and 57 of the carrier C and the thickness of the standard substrate Wt. The inter-standard substrate center position CPO is located in the middle of the length obtained by excluding the thickness of the standard substrate Wt from the interval between the upper and lower locking portions 57 and 57. If the substrate W accommodated in the carrier C is the same as the standard substrate Wt, the insertion height of the hand 19 is the inter-standard substrate center position CPO. Note that the standard substrate Wt is a test substrate W that is not warped or a substrate W represented by virtual data that is not warped.

The right diagram of FIG. 10A is a diagram indicating an inter-individual substrate center position CP1. The inter-individual substrate center position CP1 is an inter-substrate center position obtained by optimizing the inter-standard substrate center position CP0 in accordance with the shape of the substrate W. In the near-infrared image illustrated in the right diagram of FIG. 10A, the warped substrates W1 are accommodated in the upper stage, the middle stage, and the lower stage. First, when taking out the warped substrate W1 in the upper stage, whether or not to set the insertion height of the hand 19 as the inter-standard substrate center position CP0 is determined. This determination is made based on whether or not the inter-substrate gap information GPw comes into contact with either the upper and lower substrates W1, W1 when the hand 19 is advanced and retreated at the inter-standard substrate center position CP0. For this determination, the inter-substrate gap information GPw1 at the insertion position of the hand 19 in the width direction Y is used. Although not illustrated, in a case where the hand 19 is advanced and retreated at the inter-standard substrate center position CP0, when the inter-substrate gap information GPw1 is a value that does not come into contact with the substrates W1 and W1, the insertion height of the hand 19 remains at the inter-standard substrate center position CP0. In a case where the hand 19 is advanced and retreated at the inter-standard substrate center position CP0, when the inter-substrate gap information GPw1 is a value that comes into contact with the substrates W1 and W1, whether or not to change the insertion height of the hand 19 to the inter-individual substrate center position CP1 is determined.

Specifically, in a case where the hand 19 is advanced at the inter-standard substrate center position CP0, when the length from the lower end of the hand 19 to the lower end of the inter-substrate gap information GPw1 exceeds a contact threshold value serving as a reference for contact determination defined in advance, determination is made that the hand 19 does not come into contact with the substrate W on the lower side. Furthermore, when the length from the upper end of the hand 19 to the upper end of the inter-substrate gap information GPw1 exceeds the contact threshold value, determination is made that the hand 19 also does not come into contact with the substrate W on the upper side. As a result, determination is made that the hand 19 can be inserted. On the other hand, when the length from the lower end of the hand 19 to the lower end of the inter-substrate gap information GPw1 is less than the contact threshold value, determination is made that the hand 19 comes into contact with the substrate W on the lower side. Furthermore, when the length from the upper end of the hand 19 to the upper end of the inter-substrate gap information GPw1 is less than the contact threshold value, determination is made that the hand 19 comes into contact with the substrate W on the upper side. When any of less than the contact threshold value is met, determination is made that the hand 19 cannot be inserted.

The inter-individual substrate center position CP1 is an intermediate position of the value of the inter-substrate gap information GPw1. In a case where the hand 19 does not come into contact with the substrates W1 and W1 when being advanced and retreated at the inter-individual substrate center position CP1, the insertion height of the hand 19 is changed to the inter-individual substrate center position CP1. In this case, in which direction of the vertical direction Z the inter-individual substrate center position CP1 is located with respect to the inter-standard substrate center position CP0 is determined. In addition, the length of the gap GP1 between the inter-standard substrate center position CP0 and the inter-individual substrate center position CP1 is calculated. Then, the hand 19 is moved by the length of the gap GP1 in the determined direction. In a case where the hand 19 comes into contact with the substrates W1 and W1 when being advanced and retreated at the inter-individual substrate center position CP1, the advancement and retreat of the hand 19 are prohibited.

When taking out the warped substrate W1 in the middle stage, the inter-substrate gap information is obtained similarly to when taking out the warped substrate W1 in the upper stage. Note that when taking out the warped substrate W1 in the middle stage, whether or not the shape of the warped substrate W1 in the lower stage is the same as the shape of the warped substrate W1 in the middle stage may be determined. In this case, if the two shapes are the same, the same inter-substrate gap information GPw1 as when taking out the warped substrate 1 in the upper stage may be used, and if the two shapes are different, the inter-substrate gap information may be obtained in the same manner as described above. The determination described above may be performed by the control unit CU based on the information acquired by the image processing unit 53, or may be performed by the image processing unit 53 and the result may be transmitted to the control unit CU.

When the indexer robot IR sequentially takes out the substrates W accommodated in the carrier C from the top to the bottom, the indexer robot IR can retreat the hand 19 that has lifted the substrate W without coming into contact with the substrate W1 in the upper side as long as the hand 19 can be advanced between the substrates W. Therefore, it is important whether or not the hand 19 can be advanced without coming into contact with either the upper and lower substrates W. When the indexer robot IR sequentially takes out the substrates W accommodated in the carrier C from the bottom to the top, even if the hand 19 can advance between the substrates W, the hand 19 may come into contact with the substrate on the upper side when retreating the hand 19 that has lifted the substrate W. In this case, when retreating the hand 19 that has lifted the substrate W, it is also important whether or not the hand 19 can be retreated without coming into contact with the substrate W on the upper side. In addition, whether or not to come into contact with the substrate W on the upper side when the hand 19 that has lifted the substrate W is retreated may be determined using the inter-substrate gap information GPw1.

The left diagram of FIG. 10B is the same as the left diagram of FIG. 10A. The right diagram of FIG. 10B is a diagram indicating an inter-individual substrate center position CP2. In the near-infrared image illustrated in the right diagram of FIG. 10B, a warped substrate W1 is accommodated in the upper stage, a laminated substrate W2 is accommodated in the middle stage, and a warped substrate W1 is accommodated in the lower stage. A case where the warped substrate W1 in the upper stage is taken out will be described. The inter-substrate gap information GPw2 is calculated by the same method as the inter-substrate gap information GPw1. When the warped substrate W1 in the upper stage is taken out, the inter-substrate gap information GPw2 is a value at which there is no contact with either of the upper and lower substrates W1 and W2 even if the hand 19 is advanced at the inter-standard substrate center position CP0. Therefore, the indexer robot IR advances the hand 19 at the inter-standard substrate center position CP0. When the laminated substrate W2 in the middle stage is taken out, the laminated substrate W2 in the middle stage is more convexly curved downward than the warped substrate W1 in the upper stage. Therefore, the inter-substrate gap information GPw3 is a value at which there is contact with either the upper and lower substrates W1 and W2 when the hand 19 is advanced at the inter-standard substrate center position CP0. Therefore, the indexer robot IR advances the hand 19 at an inter-individual substrate center position CP2 to which the hand 19 has been moved by the length of the gap GP2 that is the difference between the inter-standard substrate center position CP0 and the inter-individual substrate center position CP2 to the lower side in the vertical direction z of the inter-standard substrate center position CP0. In this manner, the indexer robot IR can reduce damage of the substrate W when advancing and retreating the hand 19 by accurately measuring the shape of the substrate W.

The correspondence relationship between the first example described above and the present invention is as follows.

The “carrier C” corresponds to the “carrier” in the present invention. The “hand 19” corresponds to the “holding hand” of the present invention. The “indexer robot IR” corresponds to a “transporting unit” in the present invention. The “near-infrared rays” correspond to “light in a wavelength region longer than visible light” in the present invention. The “imaging unit 21” and the “image processing unit 53” correspond to the “acquisition unit” in the present invention. The “control unit CU” corresponds to the “control unit” of the present invention. The “carry-in/out block 3” and the “indexer block 5” correspond to the “substrate transporting device” of the present invention. Furthermore, the “imaging unit 21” corresponds to the “imaging unit” of the present invention. The “center position Wc of the substrate W in the depth direction” corresponds to a “predetermined position of the substrate in the depth direction”. The “lid opening/closing mechanism 41” corresponds to an “opening mechanism” of the present invention. The “image processing unit 53” corresponds to a “gap information acquisition unit”. Furthermore, the “upper edge portion W_{Ue}” corresponds to the “upper edge portion” of the present invention.

The present invention is not limited to the above embodiment, and can be modified as follows.

(1) In the present first example, the substrate processing device 1 having the configuration as illustrated in FIG. 1 has been described as an example. However, the present invention is not limited to such a mode. That is, the configuration of the indexer block 5 or the processing block 7 does not matter.

(2) In the present first example, it has been described that the substrate W having a circular shape in plan view is processed. However, the present invention is not limited to such a mode. That is, the shape of the substrate W may be a quadrangular shape or the like.

(3) In the present first example, the inter-substrate gap information GPw1, GPw2, and GPw3 at the insertion position of the hand 19 in the width direction Y have been described as an example of the inter-substrate gap information GPw. However, the inter-substrate gap information GPw is not limited to the insertion position of the hand 19 in the width direction Y. The inter-substrate gap information GPw may be, for example, a height of a gap between the lowermost point W_{L1} of the substrate W on the upper side and the upper edge portion W_{Ue} of the substrate W on the lower side. Based on such gap information, the control unit CU can determine whether or not to at least insert the hand 19.

(4) In the present first example, the warped substrate W1 along the bowl shape and the laminated substrate W2 have been described. However, the substrate W may have other warped shapes.

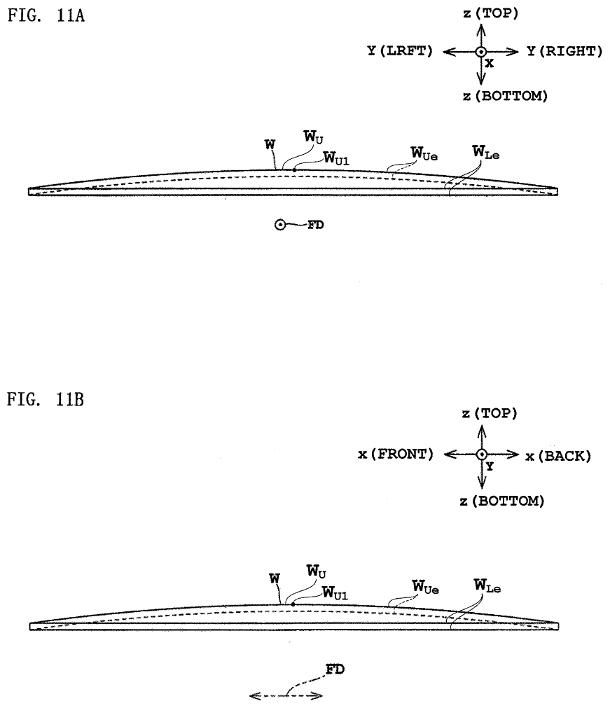

FIG. 11 illustrates a substrate W warped in an umbrella shape. The substrate W illustrated in FIG. 11 has a shape obtained by up-down inverting the substrate W warped in a bowl shape in FIG. 5 described above. In the umbrella shaped substrate W, an outer peripheral edge (lower edge portion W_{Le}) is located at a position lower than a central portion, and the central portion is raised higher than the outer peripheral edge. In other words, in the umbrella shaped substrate W, the central portion is raised, and the outer peripheral edge is at a low position. The substrate W warped in a bowl shape in this manner has a narrow upper interval in the vertical direction Z with respect to the substrate W accommodated above such substrate W in the carrier C. As can be seen from FIGS. 11A and 11B, the uppermost surface W_{U} of the substrate W is higher than the height of the end face of the lower edge portion W_{Le} in the vertical direction Z.

Here, the highest place of the uppermost surface W_{U} is referred to as an uppermost point W_{U1}. The uppermost point W_{U1} corresponds to the highest place of the upper edge portion W_{Ue}. In a case of measuring the substrate W in FIG. 11, the image processing unit 53 measures the substrate W at the central portion including at least the uppermost point W_{U1}. In such a case, the image processing unit 53 virtually sets the lower edge portion W_{Le} with respect to the tomographic image of the substrate W at the central portion, and determines the advancement disabled region GS3 where the hand 19 cannot enter. In the case of the present modified example, the “lower edge portion W_{Le}” corresponds to the “upper edge portion” of the present invention.

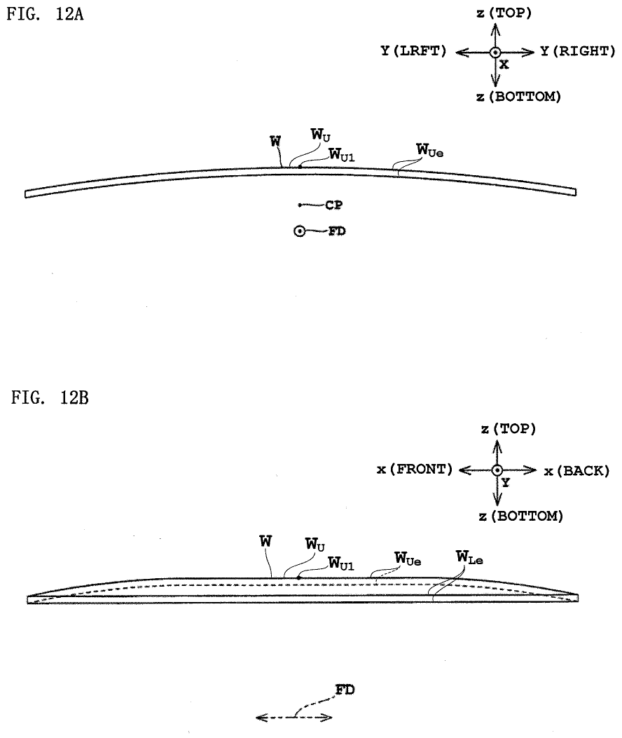

FIG. 12 illustrates a substrate W warped in a half-pipe shape. In the substrate W illustrated in FIG. 12, the surface of the substrate W is separated around the axis CP on the center side as if the cylinder is cut at the axis CP on the center side. That is, the half-pipe shaped substrate W is warped in an arc shape when viewed from the axis CP direction on the center side. The half-pipe shaped substrate W has an outer peripheral edge located at a low position and a central portion raised. However, unlike the bowl shape and the umbrella shape described above, the shape of the outer edge of the substrate W is different when viewed from the front-back direction X and when viewed from the width direction Y. In other words, the shape of the outer edge of the substrate W is different between when viewed from the front-back direction X and when viewed from the width direction Y. The substrate W warped in a half-pipe shape in this manner has a narrow upper interval in the vertical direction Z with respect to the substrate W accommodated above such substrate W in the carrier C. As can be seen from FIGS. 12A and 12B, the uppermost surface W_{U} of the substrate W is higher than the height of the end face of the lower edge portion W_{Le} in the vertical direction Z. In FIG. 12, the axis CP on the center side is the front-back direction X, but the axis CP on the center side may be the width direction Y. Note that a substrate warped in a half pipe shape as if up-down inverted in FIG. 12 may be accommodated in the carrier C.

Here, the highest place of the uppermost surface W_{U} is referred to as an uppermost point W_{U1}. The uppermost point W_{U1} corresponds to the highest place of the upper edge portion W_{Ue}. In a case of measuring the substrate W in FIG. 12, the substrate W is measured at the central portion including at least the uppermost point W_{U1}. In such a case, the lower edge portion W_{Le} is virtually set with respect to the tomographic image of the substrate W at the central portion, and the advancement disabled region GS3 where the hand 19 cannot enter is determined. In the case of the present modified example, the “lower edge portion W_{Le}” corresponds to the “upper edge portion” of the present invention.

(5) In the present first example, the imaging unit 21 is provided in the indexer block 5, but the imaging unit 21 may be arranged at a place different from the indexer block 5.

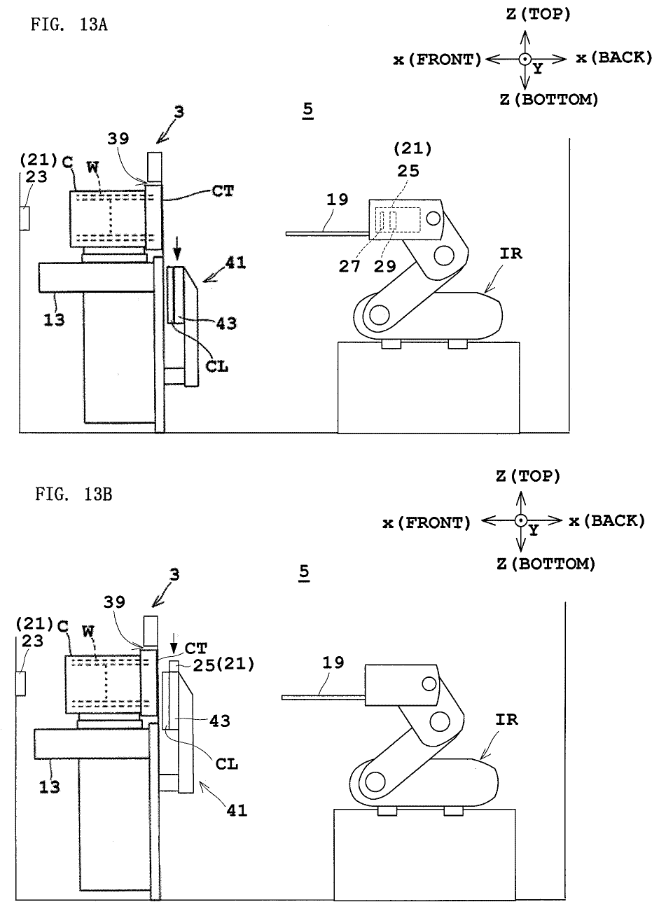

FIGS. 13A and 13B are diagrams illustrating an arrangement of the imaging unit 21 according to the modified example.

In FIG. 13A, the near-infrared irradiation unit 23 of the imaging unit 21 is provided outside the indexer block 5, for example, on a wall portion located in front of the placement table 13. The near-infrared camera 25 of the imaging unit 21 is provided in the indexer robot IR. The near-infrared irradiation unit 23 of the wall portion is disposed at a height capable of irradiating the substrate W accommodated in the carrier C with near-infrared rays. The near-infrared rays emitted from the wall portion do not transmit through the edge portion of the substrate W, and transmit through the other portions. In the near-infrared camera 25, measurement is performed in a system that transmits through the center portion and reflects on the edge portion. Therefore, a near-infrared image in which shading is inverted from that in the first example can be acquired. Note that the near-infrared irradiation unit 23 and the near-infrared camera 25 may be disposed opposite to each other.

In FIG. 13B, the near-infrared irradiation unit 23 of the imaging unit 21 is provided outside the indexer block 5, for example, on a wall portion located in front of the placement table 13. The near-infrared camera 25 of the imaging unit 21 is provided at the upper end portion of the lid opening/closing mechanism 41. Thus, the substrate W accommodated in the carrier C can be imaged by the near-infrared camera 25 in accordance with the downward movement in the vertical direction Z in a state where the lid opening/closing mechanism 41 holds the lid CL. At this time, the indexer robot IR does not need to move in accordance with the near-infrared camera 25. Therefore, if the insertion of the hand 19 is permitted after the end of the imaging by the near-infrared camera 25, the substrate W can be quickly carried out. Note that the near-infrared irradiation unit 23 may be attached to the upper end portion of the lid opening/closing mechanism 41 together with the near-infrared camera 25.

(6) In the present first example, the imaging unit 21 sequentially images the substrates W accommodated in the carrier C while moving a plurality of imaging positions in the order of the upper left, the lower left, the lower center, the upper center, the upper right, and the lower right, and carries out the substrates W after imaging of all the substrates W is finished. However, the method of imaging and carrying out the substrate W is not limited thereto.

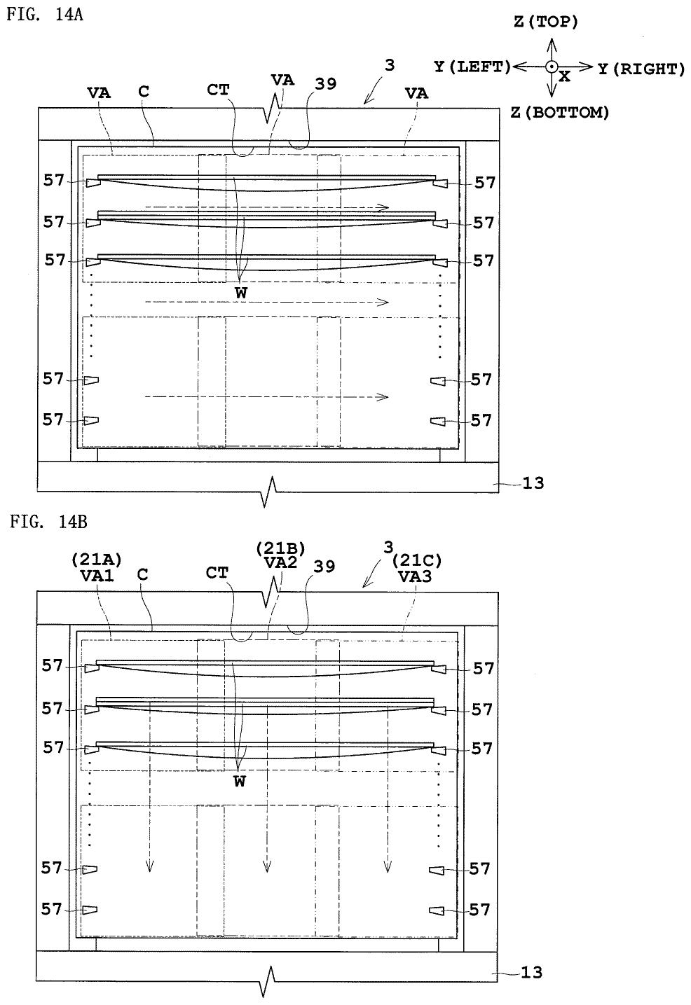

FIGS. 14A and 14B are views illustrating a method of imaging the substrate W according to the modified example.

In FIG. 14A, the indexer robot IR alternately performs imaging of the substrate W accommodated in the carrier C by the imaging unit 21 and carrying out of the substrate W. Specifically, the indexer robot IR moves from left to right such that the imaging unit 21 performs imaging in the field range VA in the order of left, center, and right with the substrates W in the first to third rows as imaging targets. The imaging unit 21 acquires near-infrared images of the substrates W in the first to third rows. When determination is made that the hand 19 can be inserted, the indexer robot IR moves to the center again, inserts the hand 19 between the substrates W in the first row and the second row, and carries out the substrates W in the first row and the second row. When the substrate W is finished being carried out, the indexer robot IR moves the imaging unit 21 to the left side so that the imaging unit 21 acquires near-infrared images of the substrates W in the third to fifth rows.

When the substrate W is imaged and carried out in this manner, one movement amount of the indexer robot IR can be suppressed. Therefore, the burden related to the drive mechanism of the indexer robot IR can be reduced.

In FIG. 14B, the indexer robot IR includes three imaging units 21A, 21B, and 21C. That is, the imaging units 21A, 21B, and 21C can acquire the near-infrared images of the substrates W in the three rows by one imaging in the field range VA1 in the left side, the central field range VA2, and the field range VA3 on the right side. The indexer robot IR may carry out the substrate W after the imaging of the substrate W accommodated in the carrier C by the imaging units 21A, 21B, and 21C is finished, or may alternately perform the imaging of the substrate W accommodated in the carrier C by the imaging units 21A, 21B, and 21C and the carrying out of the substrate W. In either case, the imaging time and the carry-out time can be shortened. The three imaging units 21A, 21B, and 21C are preferably arranged at the left and right end portions and the center, respectively, of the substrate when viewed from the front-back direction X. According to this arrangement, the tomographic image of the substrate W can be suitably measured.

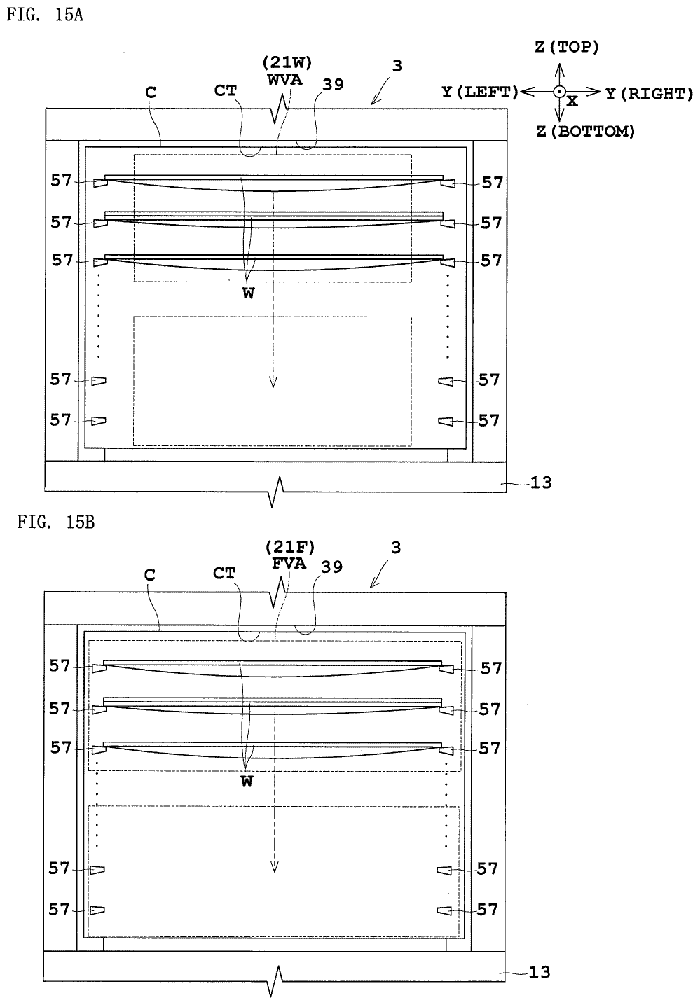

FIGS. 15A and 15B are views illustrating a method of imaging the substrate W according to a different modified example.

In FIG. 15A, the near-infrared camera 21W of a wide field range WVA wider than the field range VA is used. The near-infrared image acquired by the wide field range WVA includes a place having a large thickness necessary for measuring the shape of the substrate W and determining whether or not the hand 19 can be inserted, although both left and right end portions of the substrate W are missing. Therefore, determination on whether or not the hand 19 can be inserted can be made with sufficient accuracy. In this case as well, the indexer robot IR may carry out the substrate W after finishing the imaging of the substrate W accommodated in the carrier C by the imaging unit 21W. The indexer robot IR may alternately perform imaging of the substrate W accommodated in the carrier C by the imaging unit 21W and carrying out of the substrate W. If necessary, the image processing unit 53 may calculate the shape of the complete substrate W from the shape of the substrate W of the acquired portion.

In FIG. 15B, a near-infrared camera 21F having a full field range FVA in which substrates W of three rows are fitted up to both left and right ends is used. The near-infrared image acquired by the full field range FVA includes up to the left and right ends of the substrates W of three rows. Therefore, determination on whether or not the hand 19 can be inserted can be made with high accuracy. In addition, since the imaging unit 21F becomes compact, the weight of the indexer robot IR can be reduced. In addition, the power consumption related to the driving of the indexer robot IR can be reduced.

(7) In the present first example, the case where the substrate W is carried out has been described as an example, but application can also be made to a case where the substrate W is carried into the carrier C. That is, when the next substrate W is carried into the carrier C in a state where a certain substrate W is carried into the carrier C, the substrate W is carried into the carrier C at the inter-standard substrate center position CPO, so that the inter-individual substrate center position is calculated when the hand 19 comes into contact with the previously carried-in substrate W. As a result, damage to the substrate W can be prevented even when carrying-in the substrate W into the carrier C.

(8) In the present first example, the case where the indexer robot IR carries out the substrate W from the image of the substrate W stored in the carrier C has been described as an example. However, application may be made to a case where the indexer robot IR receives the substrate W from the delivery unit 15 or a case where the center robot CR receives the substrate W from the delivery unit 15.

(9) In the present first example, the near-infrared irradiation unit 23 and the near-infrared camera 25 have been described as examples of the imaging unit 21. However, the imaging unit 21 may use infrared rays such as short-wave infrared rays different from the near-infrared rays.

(10) In the present first example, an example in which the back surface washing unit SSR is provided as the processing unit 31 which is a processing unit has been described. However, in the present invention, the treatment unit is not limited to the washing process. The present invention may include a processing unit that performs predetermined process, for example, resist application, development process, and the like on the substrate W.

(11) In the present first example, the image processing unit 53 virtually sets the upper edge portion with respect to the tomographic image of the substrate W measured at the central portion of the substrate W, and determines the advancement disabled region GS3 where the hand 19 cannot enter. However, the present invention is not limited thereto. The image processing unit 53 may actually perform measurement using the near-infrared camera 25 without virtually setting the upper edge portion. In this case, after the central portion of the substrate W is measured by the near-infrared camera 25, the image processing unit 53 may change the position of the lens 27 with respect to the image forming plane of the near-infrared camera 25 and perform measurement with the upper edge portion of the substrate W as the focusing position. Even in the case of the present modified example, the same effects as those of the first example can be obtained.

The present invention may be embodied in other specific forms without departing from the spirit or essential attributes thereof and, accordingly, reference should be made to the appended claims, rather than to the foregoing specification, as indicating the scope of the invention.

What is claimed is:

1. A substrate transporting device for transporting a substrate with a carrier capable of stacking and accommodating a plurality of substrates with a gap and having a carry-in/out port on one side surface, the device comprising:
a transporting unit including a holding hand that holds the substrate, the transporting unit being configured to transport the substrate by advancing/retreating the holding hand to/from the carry-in/out port of the carrier to the gap between the substrates;
an acquisition unit configured to acquire shape information of the substrate when the substrate is viewed in an advancing/retreating direction of the holding hand and from a carry-in/out port side of the carrier in a state where the substrate is accommodated in the carrier; and
a control unit configured to control the transporting unit based on the shape information, wherein
the acquisition unit obtains the shape information of the substrate by irradiating light in a wavelength region longer than visible light from the advancing/retreating direction of the holding hand.

2. The substrate transporting device according to claim 1, wherein the light in the wavelength region longer than the visible light is light in a wavelength region that transmits through an inside of the substrate.

3. The substrate transporting device according to claim 1, wherein the light in the wavelength region longer than the visible light is light in a near-infrared wavelength region.

4. The substrate transporting device according to claim 1, wherein the shape information is a cross-sectional shape of the substrate at a predetermined position in the advancing/retreating direction of the holding hand.

5. The substrate transporting device according to claim 4, wherein the predetermined position is a central portion of the substrate accommodated in the carrier.

6. The substrate transporting device according to claim 1, wherein the shape information includes a shape of an upper edge portion of the substrate accommodated in the carrier.

7. The substrate transporting device according to claim 1, wherein the acquisition unit includes an imaging unit configured to image the substrate accommodated in the carrier using light in the wavelength region longer than the visible light and acquire a substrate image, and acquires the shape information from the substrate image.

8. The substrate transporting device according to claim 7, wherein the imaging unit is included in the transporting unit.

9. The substrate transporting device according to claim 7, further comprising:
a placement portion on which the carrier is placed; and
an opening mechanism configured to open a door of the carrier placed on the placement portion, wherein
the imaging unit images the substrate in a state in which the opening mechanism has opened the door or in a process of the opening mechanism opening the door.

10. The substrate transporting device according to claim 9, wherein the imaging unit is included in the opening mechanism.

11. The substrate transporting device according to claim 1, further comprising:
a gap information acquisition unit configured to acquire gap information between the substrates into which the transporting unit advances based on the shape information of the plurality of substrates accommodated in the carrier, wherein
the control unit controls the transporting unit based on the gap information.

12. The substrate transporting device according to claim 11, wherein the control unit adjusts an insertion height position of the holding hand based on the gap information.

13. A substrate processing device comprising:
a substrate transporting device for transporting a substrate with a carrier capable of stacking and accommodating a plurality of substrates with a gap and having a carry-in/out port on one side surface;
a processing unit configured to perform a predetermined process on a substrate transported by the substrate transporting device;
a transporting unit including a holding hand that holds the substrate, the transporting unit being configured to transport the substrate by advancing/retreating the holding hand to/from the carry-in/out port of the carrier to the gap between the substrates;
an acquisition unit configured to acquire shape information of the substrate when the substrate is viewed in an advancing/retreating direction of the holding hand and from a carry-in/out port side of the carrier in a state where the substrate is accommodated in the carrier; and
a control unit configured to control the transporting unit based on the shape information, wherein
the acquisition unit obtains the shape information of the substrate by irradiating light in a wavelength region longer than visible light from the advancing/retreating direction of the holding hand.
